(19) United States
(12) Patent Application Publication
(10) Pub. No.: US 2010/0055584 A1
(43) Pub. Date: Mar. 4, 2010

(54) EXPOSURE DEVICE AND EXPOSURE METHOD

(76) Inventors: Takashi SATO, Kanagawa (JP); Kazuya Fukuhara, Tokyo (JP); Yumi Nakajima, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/548,154

(22) Filed: Aug. 26, 2009

(30) Foreign Application Priority Data
Aug. 29, 2008 (JP) 2008-220804

(51) Int. Cl. G03F 9/00; G03F 7/20; G03B 27/54

(52) U.S. Cl. 430/22; 355/67

(57) ABSTRACT

An exposure device according to an embodiment includes an exposure light source for irradiating a reflective mask with an exposure light, an alignment light source for irradiating the reflective mask with an alignment light and an optical element having a structure that a light path of the exposure light extending from the alignment light source to the reflective mask shares at least part in common with a light path of the alignment light extending from the alignment light source to the reflective mask.

### CROSS-REFERENCE TO RELATED APPLICATIONS

This application is based upon and claims the benefit of priority from prior Japanese Patent Application No. 2008-220804, filed on Aug. 29, 2008, the entire contents of which are incorporated herein by reference.

### BACKGROUND

Recently, in accordance with miniaturization of a circuit pattern of semiconductor device, an exposure device is developed that uses an extra ultra violet light (an EUV light) having a wavelength of 5 nm to 100 nm as an exposure light. The EUV light is largely absorbed by substance so that a lens can not be used in an optics system but a reflective optical element such as a mirror is used, and a reflective mask is used as a photo mask. The exposure device is, for example, disclosed in JP-A-2005-32889, JP-A-2000-100697 and JP-A-2004-228215. Further, the exposure device is needed to have a high alignment accuracy.

The exposure device is disclosed in JP-A-2005-32889 irradiates alignment marks on the reflective mask with an ultra violet light via a light path different from a light path of the EUV light for exposure, and carries out an alignment of a mask stage by detecting the reflected light by a sensor.

The exposure device is disclosed in JP-A-2000-100697 carries out an alignment of a wafer stage by emitting the EUV light for exposure, the ultra violet light, a visible light and lights having the other wavelengths from a single laser light source, irradiating the reflective mask with a light selected from the above-mentioned lights by a wavelength selection device, and detecting the reflected light by a sensor disposed on the wafer stage.

JP-A-2004-228215 discloses an exposure device where an alignment light having the same wavelength as the exposure light is irradiated from the same light source as the exposure light.

### BRIEF SUMMARY

An exposure device according to an embodiment includes an exposure light source for irradiating a reflective mask with an exposure light, an alignment light source for irradiating the reflective mask with an alignment light and an optical element having a structure that a light path of the exposure light extending from the alignment light source to the reflective mask shares at least part in common with a light path of the alignment light extending from the alignment light source to the reflective mask.

An exposure method according to another embodiment includes irradiating a reflective mask with an alignment light from an alignment light source so that the alignment light passes through a light path which shares at least part in common with a light path of the exposure light for forming pattern, and detecting the alignment light reflected by the reflective mask by a light detector, carrying out an alignment of the reflective mask or a material to be irradiated onto which the exposure light reflected by the reflective mask is irradiated based on a detecting result of the alignment light by the light detector, and irradiating the reflective mask with the exposure light from an exposure light source via the common light path, and irradiating the material to be irradiated with the exposure light reflected by the reflective mask.

### BRIEF DESCRIPTION OF THE DRAWING

FIG. 1 is an explanatory view schematically showing a configuration example of an exposure device according to an embodiment;

FIG. 2 is an explanatory view schematically showing a configuration example of an exposure light source;

FIG. 3A is a plan view schematically showing an example of a reflective mask;

FIG. 3B is a plan view schematically showing an alignment mark for an x direction alignment;

FIG. 4 is a plan view schematically showing an example of a light receiving element; and

FIG. 5 is a graph schematically showing a relationship between a light quantity detecting signal detected by a light receiving element and coordinates of wafer stage so as to explain an alignment of focus direction.

### DETAILED DESCRIPTION

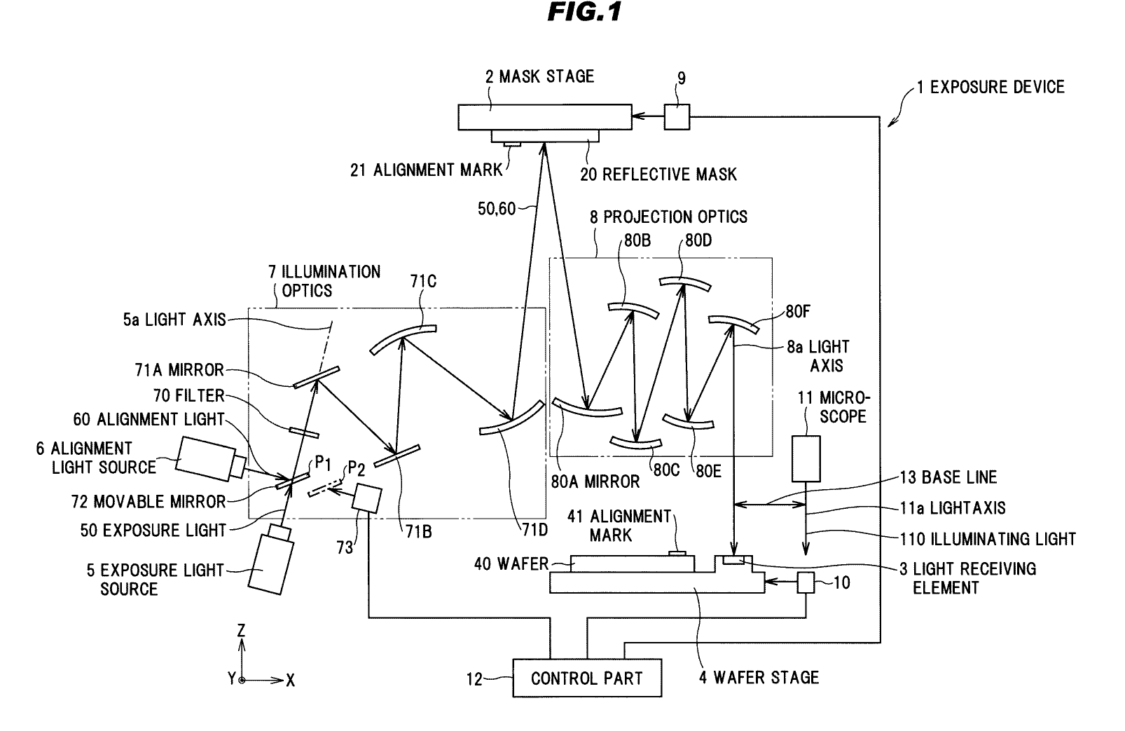

FIG. 1 is an explanatory view schematically showing a configuration example of an exposure device according to an embodiment. In FIG. 1, each of X, Y and Z shows a direction perpendicular to each other (the same is true of the other drawings).

The exposure device 1 includes a mask stage 2 on which a reflective mask 20 is disposed, a wafer stage (a workpiece stage) 4 having a light receiving element 3, on which a wafer (a workpiece) 40 is disposed where a material to be irradiated is coated, an exposure light source 5 for emitting an exposure light 50, an alignment light source 6 for emitting an alignment light 60, a illumination optics 7 for irradiating the reflective mask 20 with the exposure light 50 from the exposure light source 5 or the alignment light 60 from the alignment light source 6, a projection optics 8 for projecting the exposure light 50 or the alignment light 60 reflected by the reflective mask 20 on the mask stage 2, a mask stage drive part 9 for driving the mask stage 2, a wafer stage drive part 10 fro driving the wafer stage 4, a microscope 11 used for alignment, and a control part 12 for controlling each part of the exposure device 1.

Further, the exposure device 1 is configured to irradiate the reflective mask 20 with the exposure light 50 and the alignment light 60 via a commonly shared light path. Here, the “commonly shared light path” means a case that a main light of the alignment light 60 exists in a space through which light flux of the exposure light 50 passes, or conversely, a main light of the exposure light 50 exists in a space through which light flux of the alignment light 60 passes.

Further, as described below, an extra ultra violet (EUV) light having a wavelength of 5 to 20 nm is used as the exposure light 50 of the embodiment. The extra ultra violet (EUV) light has a property that it is scattered in an air atmosphere when it collides with atmospheric molecules, so that at least the exposure light source 5, the illumination optics 7, the reflective mask 20, the projection optics 8 and the wafer 40 are disposed in a vacuum atmosphere.

The mask stage 2 is configured to be movable in an x direction and a y direction, and the mask stage drive part 9 which allows the reflective mask 20 to move in the x and y directions is connected to the mask stage 2. Further, the mask stage 2 is configured to be able to fix the reflective mask 20 by electrostatic absorption.

The wafer stage 4 is configured to be movable in an x direction and a y direction, and the wafer stage drive part 10 which allows the wafer 40 to move in the x and y directions is connected to the wafer stage 4. Further, the wafer stage 4 is configured to be able to fix the wafer 40 by electrostatic absorption.

The control part 12 includes a CPU for controlling each part of the exposure device 1, a memory where data, programs and the like are stored. The control part 12 controls the mask stage drive part 9 and the wafer stage drive part 10 to allow the reflective mask 20 and the wafer 40 to scan in the x and y directions at a speed ratio (for example, 4:1) proportional to a reduction magnification of the projection optics 8 in synchronization with each other.

### (Exposure Light Source)

As the exposure light source 5, for example, an EUV light source for emitting the exposure light 50 of the extra ultra violet light having a wavelength of 5 to 20 nm (particularly, a wavelength of 13.5 nm) is used. As the EUV light source, for example, a laser excitation type plasma light source for exciting plasma by a laser light, a discharge type plasma light source for exciting plasma by discharging or the like can be used. In the embodiment, the laser excitation type plasma light source which has larger power than the discharge type plasma light source is used. By using the EUV light source of a wavelength of almost 5 to 20 nm, fine processing of not more than 50 nm can be carried out.

The exposure light 50 emitted from the exposure light source 5 is configured to enter into the reflective mask 20 at an inclined angle (for example, 6 degrees) to a direction perpendicular to a surface of the reflective mask 20 via the illumination optics 7, and after being reflected by the reflective mask 20, to enter into the wafer 40 from the projection optics 8 perpendicularly. The alignment light 60 is also configured to pass through the same light path as the exposure light 50, to enter into the reflective mask 20 at an inclined angle (for example, 6 degrees) to the reflective mask 20 and to enter into the light receiving element 3 perpendicularly. Detail structure of the exposure light source 5 will be explained below.

### (Alignment Light Source)

As the alignment light source 6, for example, the EUV light source which emits an EUV light having the same wavelength as the exposure light 50 can be used. As the EUV light source, the laser excitation type plasma light source, the discharge type plasma light source or the like can be used. In the embodiment, the discharge type plasma light source which has longer life and smaller power than the laser excitation type plasma light source is used. By this, the alignment light source 6 can be expected to have a long lifetime.

Further, as the alignment light source 6, a light source similar to the exposure light source 5 can be also used at low power, if it emits the alignment light 60 which has the same wavelength as the exposure light 50 and has power lower than the exposure light 50. Furthermore, as the alignment light source 6, a light source which emits a light having the other wavelength different from the EUV light such as a DUV light source for emitting a deep ultraviolet light of almost 200 nm in wavelength, an excimer laser for emitting an ultraviolet light of almost 250 nm in wavelength, a He—Ne laser for emitting a visible light of almost 633 nm in wavelength can be also used.

### (Reflective Mask)

On the reflective mask 20, an alignment mark 21 is formed and a pattern is formed based on the alignment mark 21. Further, the reflective mask 20 includes a substrate made of silica glass or the like, a reflective multilayer film for reflecting the exposure light 50 and the alignment light 60 formed on the substrate so as to have a structure that thin films having different refractive index are alternately laminated, and an absorber layer for absorbing the exposure light 50 and the alignment light 60 formed on a part of the reflective multilayer film, and the pattern and the alignment mark 21 are formed dependent on the absence or presence of the absorber layer. As the reflective multilayer film, for example, Mo—Si, Mo—Be, or the like can be used. As the absorber layer, for example, Ni, Al, Ta, Cr or the like can be used.

### (Illumination Optics)

The illumination optics 7 includes a filter (a second optical element) 70 disposed on a light axis 5a of the exposure light source 5, first to fourth mirrors 71A to 71D, a movable mirror (an optical element) 72 for irradiating the reflective mask 20 with the exposure light 50 or the alignment light 60 which is selected, disposed on the light axis 5a of the exposure light source 5 and before the filter 70, and a movable mirror drive part 73 for driving the movable mirror 72.

The filter 70 has a property of transmitting a predetermined range of wavelength (for example, 5 to 20 nm) including the wavelength (13.5 nm) of the exposure light 50 and the alignment light 60 and cutting the other wavelengths. Further, the filter 70 can be built-in the exposure light source 5 and the alignment light source 6. Here, a mirror (a second optical element) for selectively reflecting a light can be used instead of the filter 70. Namely, a mirror for increasing a reflectance to a light having a predetermined range of wavelength including the wavelength of the exposure light 50 and the alignment light 60, on the other hand, decreasing the reflectance to a light having the other wavelengths can be used. The light reflected by the mirror is led to the reflective mask 20. Furthermore, it can be also adopted that by using an element (the second optical element) where the filter and the mirror are mixed, the light having the predetermined range of wavelength including the wavelength of the exposure light 50 and the alignment light 60 is selectively led to the reflective mask 20.

The movable mirror 72 is installed so as to be movable in parallel between a first position P₁ on the light path of the exposure light 50 and a second position P₂ away from the light path. Further, the movable mirror 72 can be installed rotatably. When the movable mirror 72 is located at the first position P₁, the movable mirror 72 reflects the alignment light 60 from the alignment light source 6 to the side of the reflective mask 20 and reflects the exposure light 50 from the exposure light source 5 to a different direction from the side of the reflective mask 20. When the movable mirror 72 is located at the second position P₂, the movable mirror 72 reflects the alignment light 60 from the alignment light source 6 to a different direction from the side of the reflective mask 20 and transmits the exposure light 50 from the exposure light source 5 to the side of the reflective mask 20.

As the movable mirror drive part 73, for example, motor, solenoid or the like can be used and they are controlled by the control part 12.

FIG. 1 shows that reflecting surfaces of the first and second mirrors 71A, 71B are formed to have a flat surface, however, they can be also formed to have the other shapes, such as a concave surface, a convex surface, an aspheric surface. Further, FIG. 1 shows that reflecting surfaces of the third and fourth mirrors 71C, 71D are formed to have a concave surface, however, they can be also formed to have the other shapes, such as a flat surface, a convex surface, an aspheric surface. Furthermore, FIG. 1 shows that the number of the mirrors 71A to 71D is four, however, it can be six.

### (Projection Optics)

The projection optics 8 includes first to sixth mirrors 80A to 80E. FIG. 1 shows that reflecting surfaces of the first to sixth mirrors 80A to 80E are formed to have a concave surface, however, they can be also formed to have the other shapes, such as a flat surface, a convex surface, an aspheric surface. Further, FIG. 1 shows that the number of the mirrors 80A to 80E is six, however, it can be four or eight. The less the number of the mirrors is, the more a light use efficiency can be elevated, and the more the number of the mirrors is, the more a NA (a numeric aperture) can be increased. The NA of the projection optics 8 of the embodiment is, for example, 0.25 and the reduction magnification is, for example, ¼.

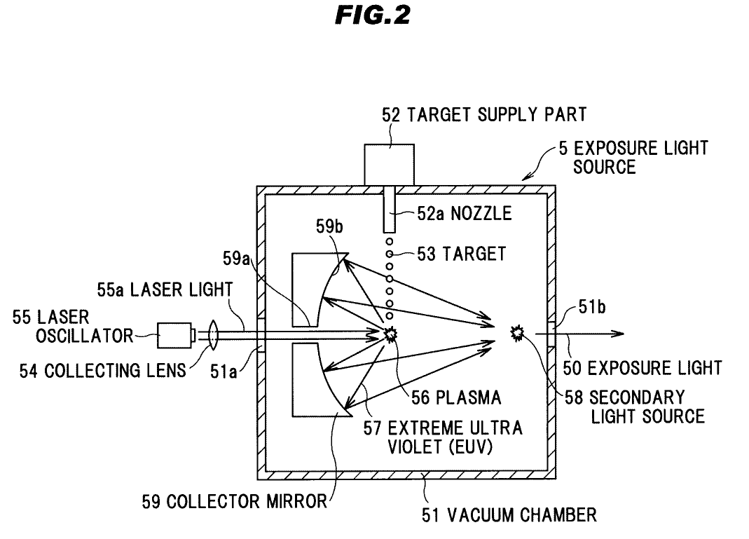

FIG. 2 is an explanatory view schematically showing a configuration example of the exposure light source 5. The exposure light source 5 includes a vacuum chamber 51, a target supply part 52 for supplying a target 53 such as xenon (Xe) gas, Sn droplet into the vacuum chamber 51 in a state of jet via a nozzle 52a, a laser oscillator 55 for irradiating the target 53 supplied into the vacuum chamber 51 with a laser light 55a via a collecting lens 54 and a window 51a so as to excite the target 53, and a collector mirror 59 for collecting an EUV light 57 at a position of a secondary light source 58, the EUV light 57 being generated together with a plasma 56 due to the excitation of the target 53. The EUV light 57 collected at the position of the secondary light source 58 is emitted as the exposure light 50 via a window 51b to the side of the reflective mask 20.

The collector mirror 59 has a hole 59a formed in the center portion thereof so as to allow the laser light 55a to pass through and a multilayer film coat 59b formed on an interior surface thereof so as to reflect the EUV light 57.

The plasma 56 also reaches the multilayer film coat 59b as well as the EUV light 57. The plasma 56 is an aggregate of particles having fairly high energy, so that it causes the multilayer film coat 59b to be damaged. Particularly, the multilayer film coat 59b is gradually scraped off, the reflectance thereof is reduced, and finally, it becomes valueless as a mirror. The exposure light source 5 has an integrated structure that the collector mirror 59 is housed in the vacuum chamber 51, so that a lifetime of the collector mirror 59 becomes a lifetime of the exposure light source 5.

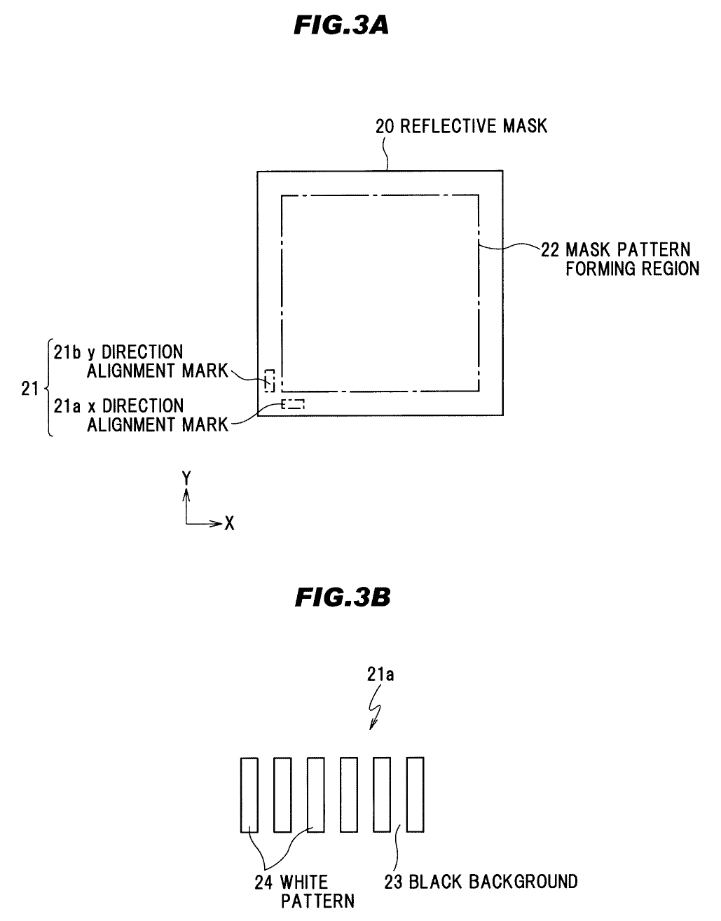

FIG. 3A is a plan view schematically showing an example of the reflective mask 20. FIG. 3B is a plan view schematically showing an alignment mark for an x direction alignment. As shown in FIG. 3A, the reflective mask 20 includes a mask pattern forming region 22 on which a mask pattern made of an absorber layer is formed, and alignment marks 21 formed on the periphery of the mask pattern forming region 22. The alignment marks 21 includes x direction alignment marks 21a used for the x direction alignment and y direction alignment marks 21b used for the y direction alignment.

As shown in FIG. 3B, the x direction alignment marks 21a includes a plurality (for example, six) of white patterns 24 which are formed by that the reflective multilayer film is exposed, and black background 23 formed of the absorber layer. The white patterns 24 are rectangular patterns having long sides and short sides and extending in the y direction, and the x direction alignment marks 21a is formed by the plural white patterns 24 arranged in the x direction.

The y direction alignment marks 21b have a pattern shape obtained when the x direction alignment marks 21a are rotated by 90 degrees.

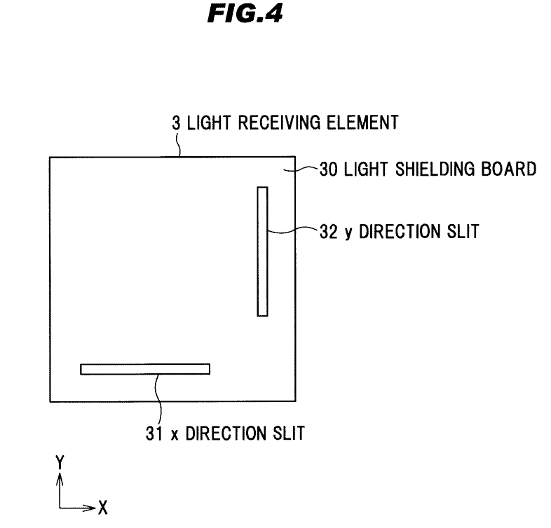

FIG. 4 is a plan view schematically showing an example of the light receiving element 3. The light receiving element 3 includes, for example, a photodiode having a light receiving surface of a rectangular shape and a light shielding board 30 disposed on the whole surface of the light receiving surface, where an x direction slit (a light receiving window) 31 and a y direction slit (a light receiving window) 32 are formed. The x direction slit 31 is a rectangular opening extending in the x and y directions slit 32 is a rectangular opening extending in the y direction.

### (Alignment Sequence)

When a superposition exposure is carried out, the reflective mask 20 is required to be exactly aligned on the wafer processed in the preceding process. Hereinafter, an alignment sequence when the superposition exposure is carried out will be explained.

### (1) Position Detection of Alignment Mark on Wafer

First, the reflective mask 20 to which the superposition exposure is carried out is fixed on the mask stage 2 by the electrostatic absorption. The reflective mask 20 is aligned on the mask stage 2 by a known aligning method. For example, the reflective mask 20 can be aligned by irradiating the alignment mark 21 with the alignment light 60, detecting it by a detecting sensor (not shown) installed in the exposure device 1, and moving the mask stage 2 in the X and y directions based on the detection result. Further, the reflective mask 20 can be also aligned by irradiating a cross shape mark on the reflective mask 20 with an ultraviolet light of 248 nm in wavelength from a cross shape mark detecting sensor (not shown) installed in the exposure device 1, detecting the reflected light by the cross shape mark detecting sensor, and carrying out the alignment based on the detection result.

Next, the wafer stage 4 is moved by the wafer stage drive part 10 in the x and y directions, being observed by the microscope 11 installed in the exposure device 1, so that an alignment mark 41 on the wafer 40 is located directly below the microscope 11. Next, coordinates of the wafer stage 4 in the x and y directions are measured by a laser interferometer (not shown). The coordinates of the wafer stage 4 are defined as coordinates (basic positions) of the alignment mark 41.

### (2) Measurement of Base Line

An illuminating light 110 is emitted downwards from the microscope 11, and the x direction slit 31 and the y direction slit 32 of the light receiving element 3 are moved directly below the microscope 11. The coordinates of the wafer stage 4 in the x and y directions are measured by the laser interferometer. By this, coordinates of the light axis 11a of the microscope 11 in the x and y directions to the basic positions can be detected.

Next, the movable mirror 72 is located at the first position P₁ by the movable mirror drive part 73. The alignment light 60 is emitted from the alignment light source 6, the alignment light 60 is irradiated onto the alignment mark 21 on the reflective mask 20 via the illumination optics 7, and the mask stage 2 is moved in the x and y directions by the mask stage drive part 9 so that the reflected light enters into the x direction slit 31 of the light receiving element 3 via the projection optics 8. The coordinates in the y direction of the wafer stage 4 when the reflected light from the reflective mask 20 enters into the x direction slit 31 are measured by the laser interferometer. Similarly to this, the coordinates in the x direction of the wafer stage 4 when the reflected light from the reflective mask 20 enters into the x direction slit 31 by using the y direction slit 32 are measured by the laser interferometer. By this, the coordinates in the x and y directions of a light axis 8a of the projection optics 8 to the light axis 11a of the microscope 11 can be detected, and a base line 13 can be measured, the base line 13 being a distance between the light axis 11a of the microscope 11 and the light axis 8a of the projection optics 8. Further, the wafer 40 can be aligned at the desired position to the light axis 8a of the projection optics 8 by using the measurement value of the base line 13.

### (3) Alignment of Focus Direction

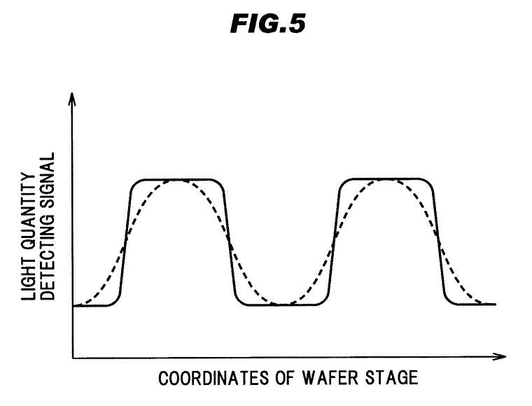

FIG. 5 is a graph schematically showing a relationship between a light quantity detecting signal detected by the light receiving element 3 and coordinates of the wafer stage 4 so as to explain an alignment of focus direction.

The alignment light 60 is emitted from the alignment light source 6 and it is irradiated onto the alignment mark 21 of the reflective mask 20 via the illumination optics 7. As the alignment mark 21, for example, an x direction alignment mark 21a can be used. The alignment light 60 is reflected at the x direction alignment mark 21a of the reflective mask 20, and then it is irradiated onto the wafer stage 4 via the projection optics 8. At this time, position in a Z direction of the wafer stage 4 is maintained at a predetermined position, and simultaneously the wafer stage 4 is scanned, for example, in the x direction, so that a light quantity can be detected by the light receiving element 3. The wafer stage 4 is moved in the z direction by a predetermined distance more than once, and the above-mentioned operation is repeated at each of the moved distances. The light quantity detected by the light receiving element 3 is an amount of a light which transmits through the y direction slit 32.

By this, for example, the light quantity detecting signal shown in FIG. 5 can be obtained. A waveform shown by a broken line in FIG. 5 shows a case that the light receiving element 3 is not located at the best focus position, and a waveform shown by a solid line in FIG. 5 shows a case that the light receiving element 3 is located at almost the best focus position. In the case that the light receiving element 3 is not located at the best focus position, rising and trailing inclinations of the light quantity detecting signal become gentle, and in the case that the light receiving element 3 is located at almost the best focus position, the rising and trailing inclinations of the light quantity detecting signal become precipitous. A position in the z direction of the wafer stage 4 where the rising and trailing inclinations of the light quantity detecting signal become the most precipitous becomes the best focus position. In case that top surfaces of the wafer 40 and the light receiving element 3 are offset, the wafer stage 4 is moved in the z direction by just distance for the offset so that the top surface of the wafer 40 becomes the best focus position. Further, the detection of light quantity can be carried out by using the y direction alignment marks 21b and the x direction slit 31.

After that, an exposure process is carried out as follows. Namely, the movable mirror 72 is located at the second position P₂ by the movable mirror drive part 73, and the exposure light 50 is emitted from the exposure light source 5. The control part 12 controls the mask stage drive part 9 and the wafer stage drive part 10 based on the measured base line to allow the reflective mask 20 and the wafer 40 to scan in the x and y directions at a speed ratio (for example, 4:1) proportional to a reduction magnification of the projection optics 8 in synchronization with each other. Due to the control, a pattern image of the reflective mask 20 can be projected onto a resist on the wafer 40.

### Advantages of Embodiment

According to the embodiment, the following advantages can be provided.

(a) The alignment light source 6 is used for the alignment separately from the exposure light source 5, so that time for replacement of the exposure light source 5 can be lengthened in comparison with a case that a light emitted from a single light source is used for the exposure and the alignment.
(b) A part of the light path which enters into the reflective mask 20 is shared by the alignment light 60 and the exposure light 50, and the alignment light 60 has the same wavelength as the exposure light 50, so that almost the same properties such as absorption, reflection, scattering as those of the exposure light 50 can be obtained, and high-accuracy alignment can be achieved.
(c) The exposure light 50 and the alignment light 60 are irradiated onto the reflective mask 20 via the filter 70, so that high-accuracy transfer of pattern image and high-accuracy alignment can be achieved.
(d) The alignment light 60 is detected via the slits 31, 32, so that the best focus position can be detected with higher resolution without use of a CCD.

### (Modification 1 of Optical System)

In the configuration shown in FIG. 1, the locations of the exposure light source 5 and the alignment light source 6 can be replaced. In this case, the movable mirror 72 is moved to the first position P₁ when the exposure light 50 from the exposure light source 5 is used, and the movable mirror 72 is moved to the second position P₂ when the alignment light 60 from the alignment light source 6 is used.

### (Modification 2 of Optical System)

In the configuration shown in FIG. 1, it can be adopted that the location of the movable mirror 72 is changed so as to be located posterior to the filter 70 and according to the change of the location of the movable mirror 72, the location of the alignment light source 6 is changed. For example, the movable mirror 72 can be located between the mirror 71D and the reflective mask 20.

### (Modification 3 of Optical System)

It can be also adopted that the alignment light 60 having wavelength different from the exposure light 50 is used, and a beam splitter through which the exposure light 50 transmits and by which the alignment light 60 is reflected, or by which the exposure light 50 is reflected and through which the alignment light 60 transmits is used as the optical element instead of the mirrors. By this, the location of the optical element can be easily adjusted.

What is claimed is:

1. An exposure device, comprising:
an exposure light source for irradiating a reflective mask with an exposure light;
an alignment light source for irradiating the reflective mask with an alignment light; and
an optical element having a structure that a light path of the exposure light extending from the alignment light source to the reflective mask shares at least part in common with a light path of the alignment light extending from the alignment light source to the reflective mask.

2. The exposure device according to claim 1, wherein the alignment light source emits the alignment light having a wavelength longer than that of the exposure light.

3. The exposure device according to claim 2, wherein the alignment light source emits the alignment light which is a visible light.

4. The exposure device according to claim 1, wherein the alignment light source emits the alignment light having the same wavelength that the exposure light has.

5. The exposure device according to claim 1, wherein the exposure light source uses a laser excitation type plasma light source as an EUV light source and the alignment light source uses a discharge type plasma light source as the EUV light source.

6. The exposure device according to claim 1, wherein the exposure light source emits the exposure light having a wavelength of 5 to 20 nm.

7. The exposure device according to claim 1, wherein the optical element is formed of movable mirrors which select the exposure light or the alignment light so as to irradiate the reflective mask, and
the device further comprises movable mirrors drive parts for driving the movable mirrors.

8. The exposure device according to claim 1, wherein the optical element is a beam splitter.

9. The exposure device according to claim 1, wherein the device comprises a second optical element which is formed on the light path of the exposure light formed from the alignment light source to the reflective mask, and is used for selecting a wavelength in a predetermined wavelength region including the wavelengths of the exposure light and the alignment light so as to lead it to the reflective mask.

10. The exposure device according to claim 1, wherein the second optical element is built-in the exposure light source and the alignment light source respectively.

11. The exposure device according to claim 1, wherein the device further comprises a mask stage on which the reflective mask are disposed and which allows the reflective mask to move a x direction and a y direction, a workpiece stage on which a workpiece is disposed where a material to be irradiated is coated and which allows the workpiece to move a x direction and a y direction, a light detector which is disposed on the workpiece stage and is used for receiving the alignment light reflected by the reflective mask, and a microscope which is used for emitting an illuminating light to the side of the workpiece stage.

12. The exposure device according to claim 11, wherein the light detector includes a photodiode and a light shielding board which is formed on a light-receiving surface of the photodiode and has a x direction slit extending in the x direction and a y direction slit extending in the y direction.

13. An exposure method, comprising:
irradiating a reflective mask with an alignment light from an alignment light source so that the alignment light passes through a light path which shares at least part in common with a light path of the exposure light for forming pattern, and detecting the alignment light reflected by the reflective mask by a light detector;
carrying out an alignment of the reflective mask or a material to be irradiated onto which the exposure light reflected by the reflective mask is irradiated based on a detecting result of the alignment light by the light detector; and
irradiating the reflective mask with the exposure light from an exposure light source via the common light path, and irradiating the material to be irradiated with the exposure light reflected by the reflective mask.

14. The exposure method according to claim 13, wherein the alignment of the reflective mask or the material to be irradiated is carried out in a focus direction by allowing a workpiece stage on which the material to be irradiated is mounted to move in a light axis direction based on the detecting result of the alignment light by the light detector.

15. The exposure method according to claim 13, wherein the light detector includes a photodiode and a light shielding board which is formed on a light-receiving surface of the photodiode and has a x direction slit extending in the x direction and a y direction slit extending in the y direction.

16. The exposure method according to claim 13, wherein the alignment light source emits the alignment light having a wavelength longer than that of the exposure light.

17. The exposure method according to claim 16, wherein the alignment light source emits the alignment light which is a visible light.

18. The exposure method according to claim 13, wherein the alignment light source emits the alignment light having the same wavelength that the exposure light has.

19. The exposure method according to claim 18, wherein the exposure light source uses a laser excitation type plasma light source as an EUV light source and the alignment light source uses a discharge type plasma light source as the EUV light source.

20. The exposure method according to claim 13, wherein the exposure light source emits the exposure light having a wavelength of 5 to 20 nm.
